(19) United States
(12) Patent Application Publication
(10) Pub. No.: US 2003/0137026 A1
(43) Pub. Date: Jul. 24, 2003

(54) Avalanche photodiode having an electrically isolated deep guard ring

(76) Inventor: Chan Yong Park, Taejon (KR)

Correspondence Address: JACOBSON, PRICE, HOLMAN & STERN, 400 Seventh Street, N.W., Washington, DC, 20004, US

(21) Appl. No.: 10/133,387

(22) Filed: Apr. 29, 2002

(30) Foreign Application Priority Data
Jan. 21, 2002 (KR) 2002-3291

(51) Int. Cl. H01L 29/861; H01L 31/107

(52) U.S. Cl. 257/481

(57) ABSTRACT

Disclosed is an avalanche photodiode for use in super-high speed optical communication, more particularly, to a structure of an avalanche photodiode device capable of suppressing edge breakdown to increase avalanche gain factor of a light signal and to reduce a noise. The avalanche photodiode includes a wafer characterized in that the guard ring has a depth equal to that of a center part of the active region (diffused region), an edge of the active region is shallower than the center part, and the guard ring is electrically isolated from the active region. Therefore, a gain-bandwidth characteristic may be increased, and also the higher receiver sensitivity may be achieved.

### BACKGROUND OF THE INVENTION

1. Field of the Invention

The present invention relates to an avalanche photodiode for use in super-high speed optical communication, and more particularly, to a structure of an avalanche photodiode device capable of suppressing edge breakdown to increase amplification of a light signal and to reduce a noise.

2. Background of the Prior Art

FIG. 1 shows a conventional avalanche photodiode (hereinafter referring to as APD) for use in super-high speed optical communication. A typical example is well known in a thesis by M. A. Itzler et al. entitled “High performance, manufacturable avalanche photodiodes for 10 Gb/s operation” Proceedings of OFC2000, FG5, 2000. Another example can be seen in a thesis by Chan-Yong Park et al. entitled “Analysis of avalanche gain with multiplication layer width and application to floating guard ring avalanche photodiode”, Inst. Phys. Conf., Ser. No 145,: chapter 8, pp. 1125-1128, IOP publishing Ltd., 1995. The conventional avalanche photodiode comprises a wafer including an n-type InP buffer layer 2 formed on an n-type InP substrate 1, an undoped (i.e., n-type) InGaAs light absorbing layer 3 formed on the InP buffer layer 2, a plurality of InGaAsP grading layers 4 formed on the InGaAs light absorbing layer 3, an n-type InP electric field adjusting layer 5 formed on the InGaAsP cladding layer 4, and an undoped (i.e., n-type) InP window layer 6 formed on the InP electric field adjusting layer 5. A guard ring 8 and a p-InP diffused region 7 are formed in a portion of the window layer 6 through Zn-diffusion as shown in FIG. 1. The diffused region 7 is shaped in such a manner that a diffused depth of an edge thereof is shallower than a depth of a center part. The guard ring 8 has a depth equal to that of the edge of diffused region 7, and is electrically isolated from the diffused region. In other words, the diffused region 7 and the guard ring 8 are maintained in a p-type condition, while a portion of the window layer located between them is remained in a n-type condition, so that the window layer is electrically isolated from the diffused region and the guard ring.

FIG. 2 shows a process of manufacturing the avalanche photodiode in FIG. 1. A wafer including an n-type InP buffer layer 2 formed on an n-type InP substrate 1, an undoped (i.e., n-type) InGaAs light absorbing layer 3 formed on the InP buffer layer 2, a plurality of InGaAsP cladding layers 4 formed on the InGaAs light absorbing layer 3, an n-type InP electric field adjusting layer 5 formed on the InGaAsP cladding layer 4, and an undoped (i.e., n-type) InP window layer 6 formed on the InP electric field adjusting layer 5 is provided by use of a crystal growth apparatus such as MOCVD or MBE (FIG. 2a). Primary Zn diffusion is performed through a diffusion window by use of silicon nitride (SiNx) (FIG. 2b). And then, secondary Zn-diffusion is performed through the diffusion window (FIG. 2c), and then a p-electrode and a passivation film of nitride silicone are formed on one surface of the wafer (FIG. 2d). After lapping and polishing a rear surface of the wafer, an n-electrode and an anti-reflection film of silicon nitride are formed on the rear surface of the wafer (FIG. 2e).

With the construction described above, an electric field generated at an edge part (indicated by reference ‘A’ in FIG. 1) of the active region is strong in relative to the electric field of the center part of the active region, so that the edge part reaches to a breakdown voltage. Therefore, it is difficult to obtain high amplification at the center part of the active region at which a light signal is converted into an electric signal to be amplified.

FIG. 3 is a graph showing the results obtained from the measurement of an avalanche gain factor of an APD having 30 Volt of the breakdown voltage. The avalanche gain factor of the edge part is almost identical to that of the center part in case of 20 V of the applied bias voltage, but the avalanche gain factor of the edge part is considerably higher than that of the center part in case of 26 V of the applied bias voltage.

If the avalanche gain factor is higher than that of the center part, it is difficult for the center part to sufficiently have a wanted avalanche gain factor, deteriorating the performance of the APD. In other words, since a light signal is incident upon the center part, only the avalanche gain factor of the central part contributes to the amplification of the light signal.

Thus, for a use of APD in super-high speed optical communication, it is required a new structure and method for suppressing an unwanted avalanche gain factor at the device edge and increasing the avalanche gain factor at the central region.

### SUMMARY OF THE INVENTION

Accordingly, the present invention is directed to an avalanche photodiode for use in super-high speed optical communication that substantially obviates one or more problems due to limitations and disadvantages of the related art.

An object of the present invention is to, for the use of APD in super-high speed optical communication, provide a new structure and method for suppressing an unwanted avalanche gain factor at a device edge and increasing avalanche gain factor at the central region.

To achieve the object and other advantages, according to one aspect of the present invention, there is provided an avalanche photodiode including a guard ring having a depth equal to that of a center part of an active region (diffused region), an edge of the active region being shallower than the center part, and the guard ring is electrically isolated from the active region.

Therefore, a gain-bandwidth characteristic may be increased, and also the higher eceiver sensitivity may be achieved.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a cross sectional view of an avalanche photodiode of the prior art;

FIGS. 2a to 2e show a process of manufacturing an avalanche photodiode in FIG. 1;

FIG. 3 is a graph showing a drawback of the prior avalanche photodiode;

FIG. 4 is a cross sectional view of an avalanche photodiode according to one preferred embodiment of the present invention;

FIG. 5 is a cross sectional view of an avalanche photodiode according to another preferred embodiment of the present invention;

FIGS. 6a to 6e show a process of manufacturing an avalanche photodiode according to the present invention; and

FIGS. 7a to 7c show strength of an electric field generated at each edge of the present invention and prior art.

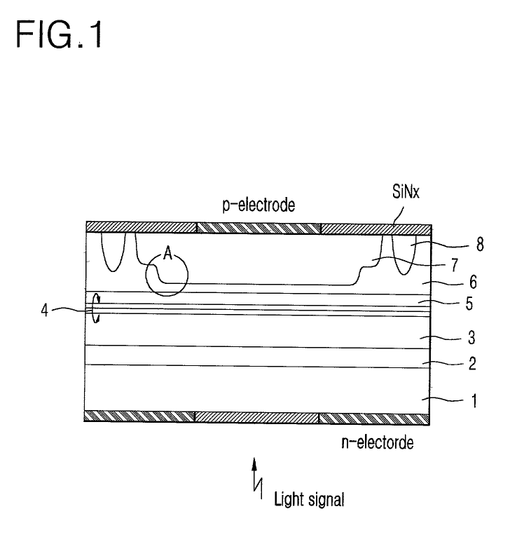

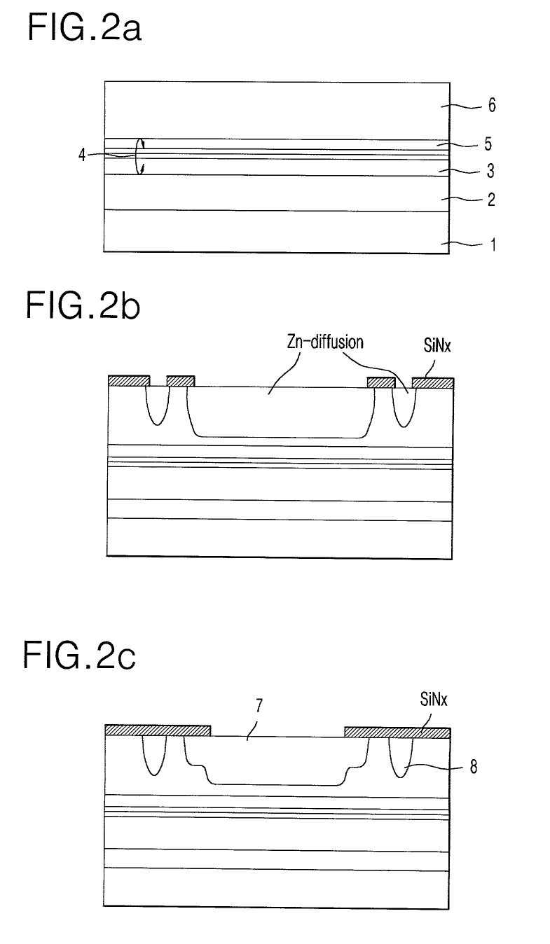

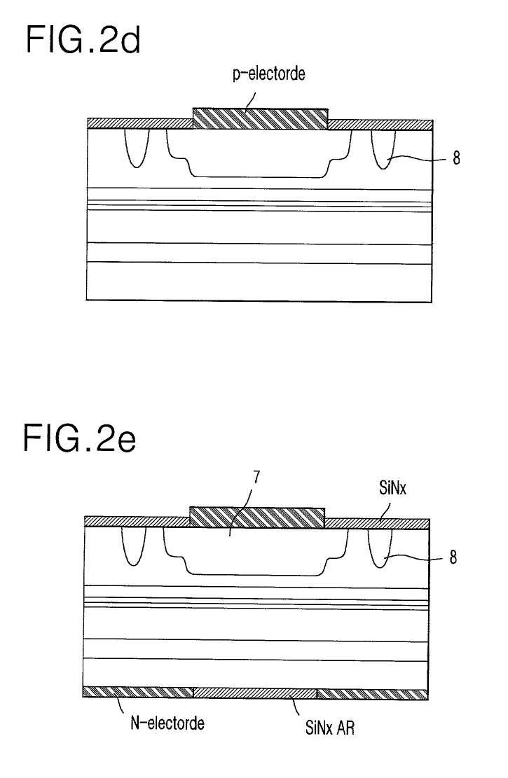

### DETAILED DESCRIPTION OF THE PREFERRED EMBODIMENTS

An avalanche photodiode according to one preferred embodiment of the present invention will now be explained with reference to the accompanying drawings.

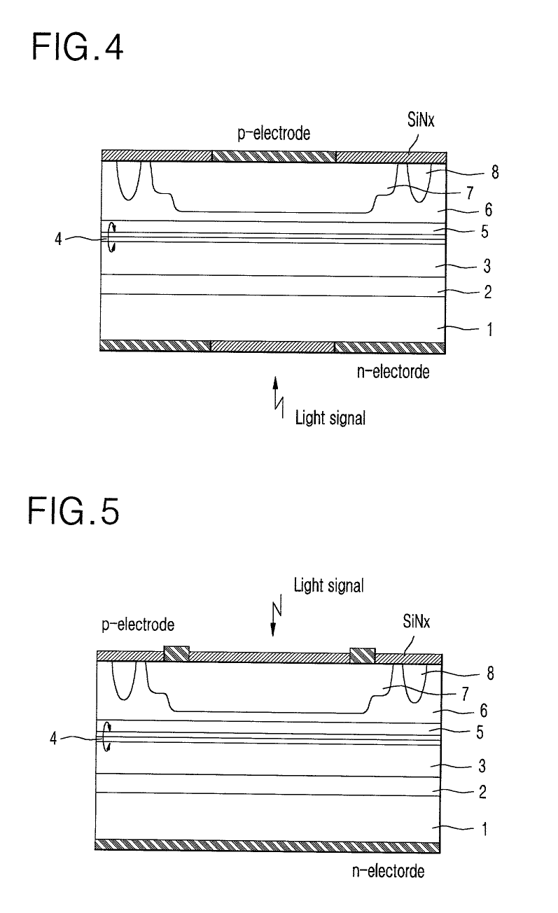

The avalanche photodiode of the present invention comprises, as shown in FIG. 4, a wafer including an n-type InP buffer layer 2 formed on an n-type InP substrate 1, an undoped (i.e., n-type) InGaAs light absorbing layer 3 formed on the InP buffer layer 2, a plurality of InGaAsP grading layers 4 formed on the InGaAs light absorbing layer 3, an n-type InP electric field adjusting layer 5 formed on the InGaAsP grading layer 4, and an undoped (i.e., n-type) InP window layer 6 formed on the InP electric field adjusting layer 5, a guard ring 8 and a p-InP active region (diffused region) 7 being formed in a portion of the window layer 6 by diffusing a p-type impurity, a passivation film such as silicon nitride and a p-electrode being layered on the surface of the wafer, and an n-electrode and an antireflection film being layered on the other surface of the wafer, characterized in that the guard ring 8 has a depth equal to that of a center part of the active region (diffused region) 7, an edge of the active region 7 is shallower than the center part, and the guard ring 8 is electrically isolated from the active region 7.

With the construction, the diffused region 7 and the guard ring 8 are maintained in a p-type condition, while a portion of the window layer located between them is not converted to the p-type, but is remained in an n-type condition, so that the guard ring is electrically isolated from the diffused central active region.

If the p-electrode is formed in a disk type to be attached to the entire of the active region, the light incident from a lower part of the device passes through the light absorbing layer 3 and the p-InP active region 7, and then is reflected by the electrode to return to the light absorbing layer 3, thereby obtaining light receiving efficiency similar to that a thickness of the light absorbing layer 3 is doubled. In addition, a contacted area between the electrode and the p-InP active region 7 is widened, thereby reducing an ohmic contact resistance.

In order to reduce the ohmic contact resistance, an ohmic contact layer such as p-InGaAsP or p-InGaAs may be located between the p-electrode and p-InP active layer.

FIG. 5 shows another embodiment of the present invention. The avalanche photodiode of another embodiment of the present invention comprises a wafer including an n-type InP buffer layer 2 formed on an n-type InP substrate 1, an undoped (i.e., n-type) InGaAs light absorbing layer 3 formed on the InP buffer layer 2, a plurality of InGaAsP grading layers 4 formed on the InGaAs light absorbing layer 3, an n-type InP electric field adjusting layer 5 formed on the InGaAsP grading layer 4, and an undoped (i.e., n-type) InP window layer 6 formed on the InP electric field adjusting layer 5, a guard ring 8 and a p-InP diffused region 7 being formed in a portion of the window layer 6 by diffusing a p-type impurity, and a passivation film such as silicon nitride, an anti-reflection film for an incident light signal, and a p-electrode being layered on the surface of the wafer, and an n-electrode layered on the other surface of the wafer, characterized in that the guard ring 8 has a depth equal to that of a center part of the active region (diffused region) 7, an edge of the active region 7 is shallower than the center part, and the guard ring 8 is electrically isolated from the active region 7.

In order to reduce the ohmic contact resistance, an ohmic contact layer such as p-InGaAsP or p-InGaAs may be located between the p-electrode and p-InP active layer.

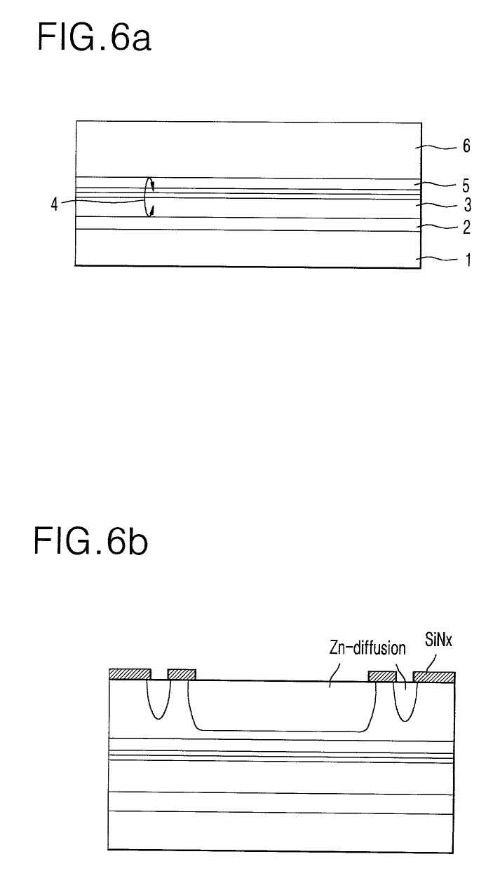

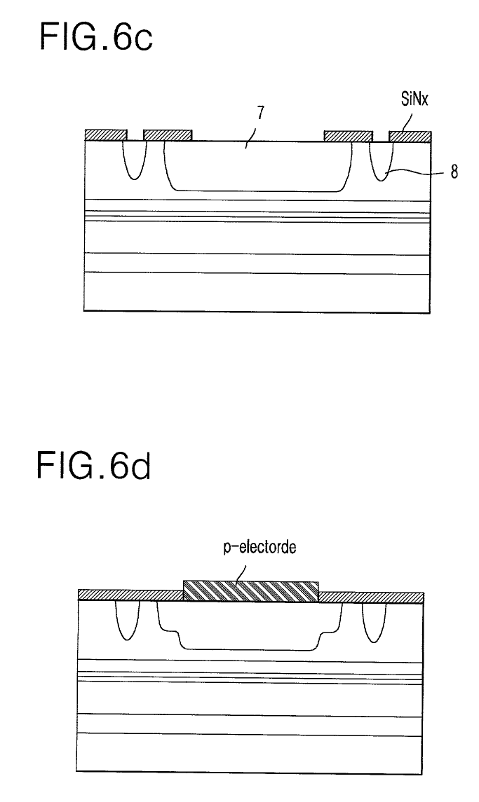

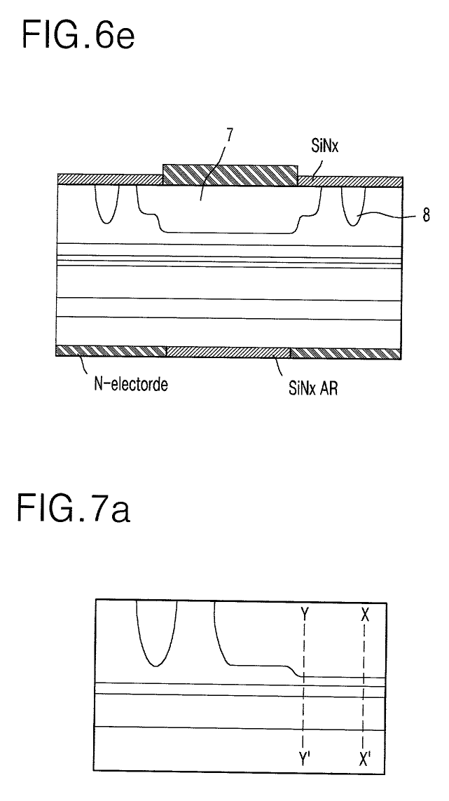

A method of manufacturing a rear incident type of avalanche photodiode according to present invention shown in FIG. 4 will now be described with reference to FIG. 6.

A wafer including an n-type InP buffer layer 2 formed on an n-type InP substrate 1, an undoped (i.e., n-type) InGaAs light absorbing layer 3 formed on the InP buffer layer 2, a plurality of InGaAsP grading layers 4 formed on the InGaAs light absorbing layer 3, an n-type InP electric field adjusting layer 5 formed on the InGaAsP grading layer 4, and an undoped (i.e., n-type) InP window layer 6 formed on the InP electric field adjusting layer 5 is provided by use of a crystal growth apparatus such as MOCVD or MBE (FIG. 6a). Primary Zn diffusion is performed through a diffusion window by use of silicon nitride (SiNx) (FIG. 6b). And then, secondary Zn-diffusion is performed through the diffusion window (FIG. 6c), and then the p-electrode and the passivation film of silicon nitride are formed on one surface of the wafer (FIG. 6d). After lapping and polishing a rear surface of the wafer, an n-electrode and an anti-reflection film of silicon nitride are formed on the rear surface of the wafer (FIG. 6e).

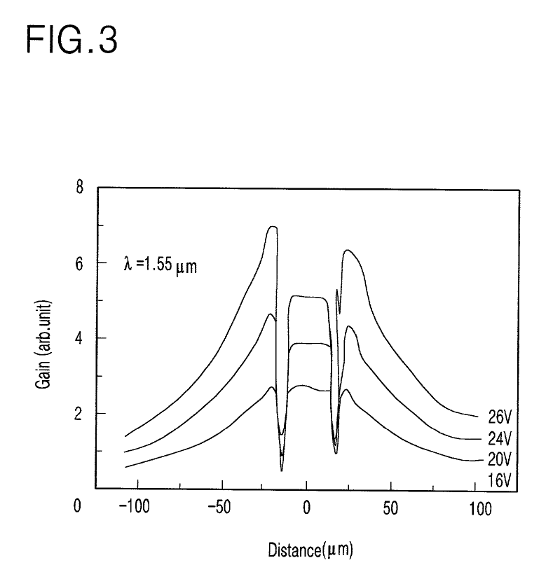

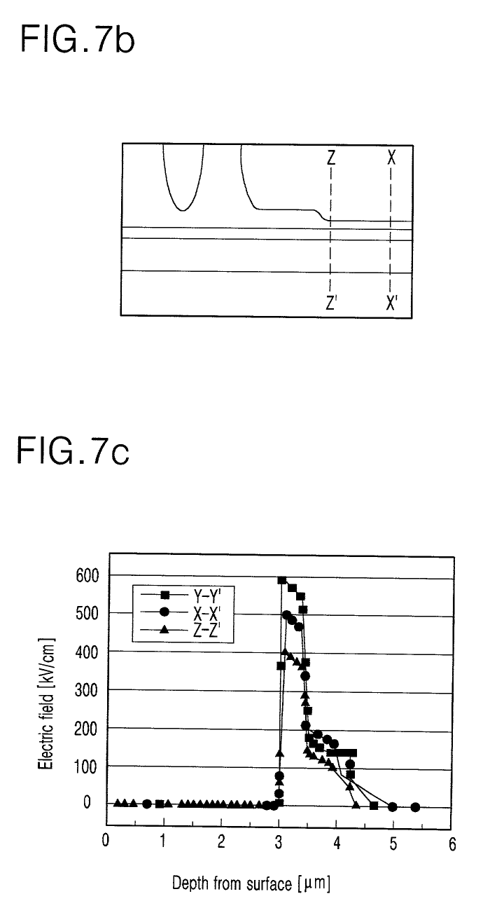

With the construction described above, the present invention suppresses considerably increased avalanche gain factor at an edge part, such as shown in FIG. 3. A principle of suppressing the avalanche gain factor of the edge part is shown in detail in FIG. 7. FIG. 7a shows a half of a cross sectional view of a conventional APD structure, in which the depth of the guard ring is equal to that of the edge part of the active region. FIG. 7b shows a half of a cross sectional view of an APD structure proposed by the present invention, in which the depth of the guard ring is equal to that of the center part of the active region. FIG. 7c is a graph showing the calculated results of electric field strength between the conventional structure and present invention. Considering the electric field generated at the center part, the electric field strength of the conventional APD is identical to that of the presently invented APD, it being indicated by a symbol X-X′ in FIG. 7c. Since the metallurgical junction at a boundary between the center part and the edge part has a curvature, the electric field of the conventional APD at a boundary between the center part and the edge part is stronger than that of the center part (referring to a symbol Y-Y′), while the electric field strength at a boundary between the center part and the edge of the presently invented APD is lower than that of the center part (referring to a symbol Z-Z′). This is because the deep guard ring of the present invention generates a negative curvature of an equipotential line when a bias voltage is applied to the device. In case of having a positive curvature like the conventional structure, the more a radius of the curvature is increased, the more increasing a breakdown voltage is (in other words, the electric field is decreased). Since the center part has infinite radius of curvature, the breakdown voltage becomes to be the maximum value at the center part (in other words, the electric field is minimized). This phenomenon is well reported by a thesis by S. M. Sze et al. in Solid state electronics, vol. 9, p. 831, 1966. If the equipotential line has the negative curvature, the breakdown voltage is increased more than that of the center part with the infinite radius of curvature (in other words, the electric field is decreased).

With the construction of the avalanche photodiode according to present invention, due to the suppression of the electric field (increase of the breakdown voltage) at the edge, the device may be manufactured by make the utmost use of the characteristic at the center part. Therefore, the present invention can increase the avalanche gain factor and reduce the noise, in contrast to that of the conventional APD. Therefore, a gain-bandwidth product may be increased, and also the receiver sensitivity may be increased.

The forgoing embodiments are merely exemplary and are not to be construed as limiting the present invention. The present teachings can be readily applied to other types of apparatuses. The description of the present invention is intended to be illustrative, and not to limit the scope of the claims. Many alternatives, modifications, and variations will be apparent to those skilled in the art.

What is claimed is:

1. An avalanche photodiode including a wafer including an n-type InP buffer layer 2 formed on an n-type InP substrate 1, an undoped (i.e., n-type) InGaAs light absorbing layer 3 formed on the InP buffer layer 2, a plurality of InGaAsP grading layers 4 formed on the InGaAs light absorbing layer 3, an n-type InP electric field adjusting layer 5 formed on the InGaAsP grading layers 4, and an undoped (i.e., n-type) InP window layer 6 formed on the InP electric field adjusting layer 5, a guard ring 8 and a p-InP active region (diffused region) 7 being formed in a portion of the window layer 6 by diffusing a p-type impurity, a passivation film such as silicon nitride and a p-electrode being layered on the surface of the wafer, and an n-electrode and an anti-reflection film being layered on the other surface of the wafer, the avalanche photodiode comprising:
the guard ring having a depth equal to that of a center part of the active region (diffused region), an edge of the active region being shallower than the center part, and the guard ring being electrically isolated from the active region.

2. The avalanche photodiode as claimed in claim 1, wherein the p-electrode is attached to the entire of the active region.

3. The avalanche photodiode as claimed in claim 1, wherein an ohmic contact layer is located between the p-electrode and p-InP active layer.

4. An avalanche photodiode including a wafer including a wafer including an n-type InP buffer layer 2 formed on an n-type InP substrate 1, an undoped (i.e., n-type) InGaAs light absorbing layer 3 formed on the InP buffer layer 2, a plurality of InGaAsP grading layers 4 formed on the InGaAs light absorbing layer 3, an n-type InP electric field adjusting layer 5 formed on the InGaAsP grading layers 4, and an undoped (i.e., n-type) InP window layer 6 formed on the InP electric field adjusting layer 5, a guard ring 8 and a p-InP diffused region 7 being formed in a portion of the window layer 6 by diffusing a p-type impurity, a passivation film such as silicon nitride, an anti-reflection film for an incident light signal, and a p-electrode being layered on the surface of the wafer, and an n-electrode layered on the other surface of the wafer, the avalanche photodiode comprising:
the guard ring having a depth equal to that of a center part of the active region (diffused region), an edge of the active region being shallower than the center part, and the guard ring is electrically isolated from the active region.

5. The avalanche photodiode as claimed in claim 4 wherein an ohmic contact layer is located between the p-electrode and p-InP active layer.
